(19) United States
(12) Patent Application Publication
(10) Pub. No.: US 2015/0353196 A1
(43) Pub. Date: Dec. 10, 2015

(54) UAV Constraint in Overhead Line Inspection

(71) Applicants: Izak Jan van Cruyningen, Saratoga, CA (US); Robert Van Wart, Staten Island, NY (US)

(72) Inventors: Izak Jan van Cruyningen, Saratoga, CA (US); Robert Van Wart, Staten Island, NY (US)

(21) Appl. No.: 14/733,962

(22) Filed: Jun. 9, 2015

Related U.S. Application Data
(60) Provisional application No. 62/009,775, filed on Jun. 9, 2014.

(51) Int. Cl. B64C 39/02; G01R 31/40; G01R 29/08

(52) U.S. Cl. CPC B64C 39/024; G01R 29/0878; G01R 31/40; B64C 2201/14; B64C 2201/107

(57) ABSTRACT

FIG. 1 shows airframe 10 with electromagnetic field sensor 12, adjustable reference electromagnetic field strength 14, comparator 16, parachute 18, parachute trigger 19, and inspection camera 20 inspecting a transmission line corridor containing towers 40, 42, and 44, phase conductors 46, 48, and 50, and shield wires 52 and 54. Reference electromagnetic field strength 14 is adjusted before the flight to set the minimum electromagnetic field strength before parachute trigger 19 deploys parachute 18. The reference electromagnetic field strength 14 corresponds to a radius, and thus virtual tunnel 22, outside of which airframe 10 cannot fly without deploying parachute 18, regardless of the state of the autopilot, GPS signal, or radio link.

### CROSS-REFERENCE TO RELATED APPLICATIONS

This application claims the benefit of provisional patent application Ser. No. 62/009,775 filed 2014 Jun. 9 by the present inventors.

### BACKGROUND

### Prior Art

This invention relates to flight paths for aerial surveys, inspections, and reconnaissance of overhead lines using unmanned aerial vehicles (UAVs). To fly a UAV safely the Federal Aviation Administration asks that you address three issues:
sense and avoid other air traffic,
maintain control even with a lost radio link, and
prevent spoofing of the control communication

This invention addresses the latter two issues for overhead line inspection by including an electromagnetic field sensor on the UAV that automatically deploys a parachute when the field strength drops below a preset value. The addition of the sensor and parachute ensure the UAV stays within a certain radius of the overhead line, thereby defining a virtual ‘tunnel’ around the overhead lines. Neither a lost radio link, nor malicious spoofing of the communication, allow the UAV out of the tunnel.

Unmanned aerial vehicles (UAV) are an excellent vehicle for close-in inspection of overhead lines. They do not require the same safety margin as manned flight, so they can be flown closer to the lines at much lower heights above ground. An autopilot using GPS signals can be programmed to fly efficient flight paths to optimize the inspection mission. As described in U.S. 61/937,048 “Efficient Flight Paths for Aerial Corridor Inspection” incorporated by reference, a typical inspection mission consists of three types of flights: right of way inspection flown near the edge of the right of way, tower inspection in circles about the tower, and close-in detailed conductor inspection in catenary arcs.

Without a human decision maker on board, UAVs suffer from the risk of flyaway. If the autopilot fails, if the GPS signals are lost, or if the wind is too strong; then the UAV no longer has control over its trajectory and it can fly away. To manage this situation, many UAVs include the ability to manually control the UAV over a radio link using radio control (RC) equipment. Regulatory agencies require UAVs to stay within line of sight of the operator. The radio link is subject to failure or spoofing, and the line of sight restriction adds substantial costs for inspection missions along overhead lines.

Flyaway prevention has been addressed with several other techniques. One approach is geofencing, where the autopilot uses the GPS signal to limit flight within a specific volume. Another approach is to automatically return to base when the GPS signal is lost or if there is no radio link communication for a predetermined amount of time. Both these approaches require a functioning autopilot.

For redundancy if the autopilot fails, many UAVs include an altimeter that is set up to automatically deploy a parachute if the altitude is too low. This reduces risk to people on the ground, but does not prevent flyaway from the planned flight path. To allow take-off and landing this altimeter safety mechanism (like the approaches described in the previous paragraph) is turned off initially, only armed once airborne, and disarmed before landing. Remotely arming and disarming while in flight allows another point of failure in the system.

An alternating current (AC) overhead line emits a very low frequency induction field that consists of
1. An electric field (E-field) whose strength depends on the line voltage and geometry. The field strength drops off very quickly away from the line, from thousands of volts per meter near the line down to ˜100 V/m at 25-50 m away. The earth's static electric field varies with the weather from ˜150 V/m in fair weather to ˜2000 V/m during thunderstorms.
2. A magnetic (B-field) whose strength varies with the current flowing in the line. The magnetic field also varies strongly with distance from the line with about a hundred microTesla near the line to less than one microTesla at 25-50 m away. The earth's magnetic field varies with geographic location from 20-80 microTesla.

High voltage direct current lines produce static fields of comparable magnitudes.

Sensors for electromagnetic field strength are well known. Most electricians carry a pencil-type detector that lights up or emits a sound when held close to energized conductors. AlphaLab under the TriField brand produces both analog and digital multiaxis electric and magnetic field meters to provide quantitative measurements. Combinova produces multiaxis magnetic and single axis electric field sensors.

Automatic parachute deployment is also well known from model rocketry. Altimeters, attitude sensors, magnetic apogee detectors, and timers are used to deploy parachutes using the energy from springs, carbon dioxide cartridges, cable cutters, or pyrodex or black powder electronic matches.

In U.S. Pat. No. 4,818,990, Fernandes describes electric field detection circuitry to maintain a UAV a fixed distance from the conductors. The electric field sensor in conjunction with Doppler radar, radio uplink, rate gyro, and altimeter provide inputs to an autopilot which performs primary navigation of the remotely piloted vehicle. Radio link failure is addressed by ascending to try to reacquire the signal or by flying a preprogrammed route. Failure of the autopilot is not addressed and a parachute is not mentioned. It would be difficult to deploy a parachute on the rotorcraft described due to the risk of entanglement in the blades.

In U.S. Pat. No. 9,037,314, Waite, Gudmundson, and Gargov describe a much more advanced system using three orthogonal magnetic field sensors and three orthogonal electric field sensors to determine UAV position, orientation, line phase, load factor, etc. They do not discuss failure nor redundancy.

CN 102591355 discusses modeling and calculation of a safe UAV flight distance away from the lines to avoid electromagnetic interference for sensitive components on the UAV. This patent does not discuss recovery from component failure nor fly-away.

CN 102591357 describes an electric field sensor connected to the motor speed controller and the main controller. When the UAV is closer than a safe distance to the lines, the main controller is notified and the motor speed is cut. This system is for collision avoidance and assumes the speed controller is still functioning correctly. This patent does not address flyaway prevention, nor parachute deployment.

The novel combination of a simple electromagnetic field detector and automatic parachute deployment described here provides a valuable safety tool for UAV flight in power line inspection and significant progress in addressing FAA safety concerns.

### SUMMARY

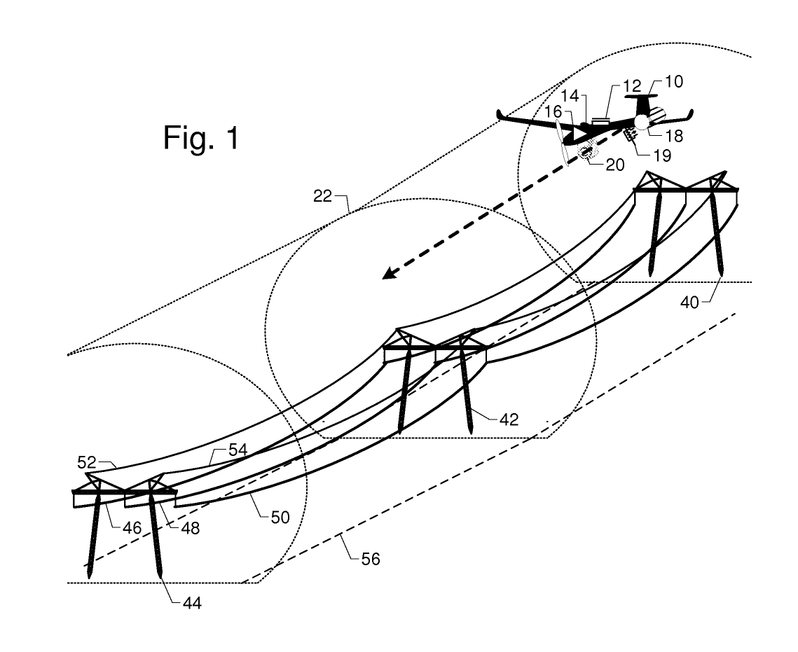

FIG. 1 shows airframe 10 with electromagnetic field sensor 12, adjustable reference electromagnetic field strength 14, comparator 16, parachute 18, parachute trigger 19, and inspection camera 20 inspecting a transmission line corridor containing towers 40, 42, and 44, phase conductors 46, 48, and 50, and shield wires 52 and 54. Reference electromagnetic field strength 14 is adjusted before the flight to set the minimum electromagnetic field strength before parachute trigger 19 deploys parachute 18. The reference electromagnetic field strength 14 corresponds to a radius, and thus virtual tunnel 22, outside of which airframe 10 cannot fly without deploying parachute 18, regardless of the state of the autopilot, GPS signal, or radio link.

### ADVANTAGES

Although electromagnetic field sensors, automatic parachute deployment, and UAV inspection of overhead lines are all well known in the prior art, the novel combination of these elements produces a method of constraining the UAV within a virtual tunnel to enhance safe operation. Various aspects of the embodiments of our UAV constraint system are superior because:
The UAV cannot fly out of the virtual tunnel, no matter if the autopilot fails, the GPS fails, the operator makes a mistake in manual control, a terrorist takes over radio control, or the wind is too strong.
The constraint system is armed before takeoff and disarmed after landing, eliminating the risk of trying to remotely arm and disarm the system while in flight.
The constraint system uses its own sensor, battery, comparator, and parachute deployment, making it completely independent of the primary navigation and control systems.

Other advantages of one or more aspects will be apparent from a consideration of the drawings and ensuing description.

### FIGURES

1. Perspective view of overhead line inspection flight path.

2. Preflight arming flowchart.

3. Schematic for analog UAV constraint circuit

4. Schematic for digital UAV constraint circuit

### DETAILED DESCRIPTION

This section describes several embodiments of the UAV constraint system with reference to FIGS. 1-4.

FIG. 1 is a perspective view of an inspection flight path for overhead lines. Airframe 10 supports electromagnetic field sensor 12, adjustable reference electromagnetic field strength 14, comparator 16, parachute 18, parachute trigger 19, and inspection camera 20. Not enumerated for clarity are standard, well-known components of an unmanned aerial vehicle used for normal navigation and flight including the power plant, control surfaces, radio control, autopilot, and GPS sensor. Towers 40, 42, and 44 support phase conductors 46, 48, and 50, as well as shield wires 52 and 54 within the right of way with boundary 56. Adjustable reference electromagnetic field strength 14 corresponds to the radius of an approximately cylindrical virtual tunnel 22, within which the UAV is constrained.

The example shown in FIG. 1 is a power transmission line but the same approach also applies to distribution, telephone, cable TV, and electric railway lines. Even overhead lines that are not normally energized, such as suspension bridge cables or guy wires for towers, can be energized for the duration of the inspection to use this constraint system.

Electromagnetic field sensor 12 can be purchased from AlphaLab, Combinova, or other vendors; or the principles and components they use can be incorporated in a custom design. Measuring the electromagnetic field can be done with electric field sensors, magnetic field sensors, or a combination. A small rectangle of conductive material such as aluminum foil will measure electric field strength in one dimension. Three rectangles on the orthogonal sides of a block can measure electric field strength in any direction. A magnetic field can be measured by Hall Effect sensors, gauss meters, induction coils, fluxgate magnetometers, and other technologies.

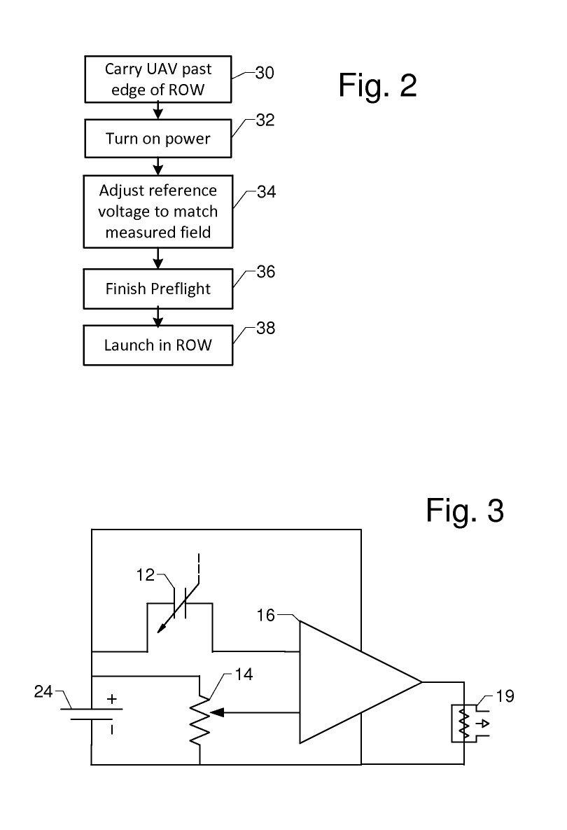

Adjustable reference electromagnetic field strength 14 is the minimum electromagnetic field strength allowed before parachute trigger 19 deploys parachute 18. This reference electromagnetic field strength can be stored as a setting of a potentiometer in an analog implementation, as described below with reference to FIG. 2. In the approach described there, adjustable reference electromagnetic field strength 14 is set during flight precheck by walking the UAV a little past the edge of right of way 56 and adjusting a potentiometer to match the field strength measured there. In a digital implementation it is stored in a memory location to be used by the processing unit. It might also be a fixed value at some multiple of the background field, or a calibrated fixed value if the UAV is used to inspect lines of comparable voltage and geometry. Another analog implementation would be to make the electromagnetic field sensor 12 have variable sensitivity or gain, and measure the adjusted gain relative to a fixed value. An analog implementation uses fewer parts and has fewer points of failure, while a digital implementation allows more flexibility.

Comparator 16 can be a simple analog signal comparator with an adjustable reference electromagnetic field strength 14 in an analog implementation. In a digital implementation it would be the comparison operator on a microprocessor. It could also be implemented as an inverter with a cutoff, a 555 timer, a zener diode, or other methods that allow comparison of one signal with another.

When comparator 16 detects a field strength below reference electromagnetic field strength 14, it signals parachute trigger 19 to deploy parachute 18. Parachute trigger 19 may be a servo, electronic match, relay, spring, CO2 cartridge, or any one of the many approaches used in model rocketry.

Airframe 10 is shown as a fixed wing vehicle. Rotary wing UAVs can also use this constraint system, provided they launch parachute 18 quickly enough to clear their blades. For example, Fruity Chutes of Los Gatos, Calif. have developed the Peregrine CO2 launch system for rapid deployment on rotary wing UAVs.

A parachute is a positive way of slowing the UAV and bringing it gently to the ground. For a fixed wing aircraft it is also possible to turn down the motors or deflect the control surfaces, but the glide slope will still allow the UAV to fly some distance away before crashing. With a motor turned down, rotary wing UAVs have much steeper glide slopes (quadcopters plummet straight down) so the flyaway distance is more constrained. However, they may hit the ground hard damaging the inspection sensors, airframe, nearby people, or nearby property.

The electromagnetic fields fall off very rapidly away from the phase conductors 46, 48, and 50. Close-in the geometry of the lines is significant to the layout of the field, but from about half a phase separation away from the outer line the drop off is monotonic. Thus reference electromagnetic field strength 14 corresponds to a radius of a cylindrical shape named a virtual tunnel 22 that constrains the UAV flight. For the single phase, three lines across system like towers 40, 42, and 44 the cylinder is wider than tall. For a double circuit with tall towers it may be taller than wide.

FIG. 2 is a flowchart illustrating one approach to adjusting the reference electromagnetic field strength 14 during preflight. The electric and magnetic field strength around power lines has been extensively studied, both theoretically and experimentally. From the desired inspection flight trajectory, the radius for virtual tunnel 22 can be determined. Then if the power line voltage and geometry are known, the reference electromagnetic field strength 14 for that radius can be calculated.

An easier approach is to measure the actual field strength for that specific line during preflight. The right of way (ROW) encroachment inspection is typically flown at the edge of the ROW 56 at an altitude of about twice the tower height. Typically it is furthest flight path from the phase conductors 46, 48, and 50. With reference to FIG. 2, the operator carries the UAV past the edge of the ROW 30. A slightly larger radius than the planned flight allows for wind gusts and piloting overshoots. After turning on the power 32, the operator adjusts the reference electromagnetic field strength 14 to match the field strength measured at that location 34. This saves the reference electromagnetic field strength 14 for the duration of the flight. Then the operator finishes the rest of the preflight 36 and launches within the right of way 38. The UAV constraint system is armed and active from the time the system is turned on until it is turned off after landing at the end of the flight during post-flight.

FIG. 3 shows a very simple analog implementation of the UAV constraint system. Battery 24 provides power to electromagnetic field strength sensor 12, reference electromagnetic field strength 14, and comparator 16. During preflight, the UAV is brought 30 a little past the right of way boundary 56 and reference electromagnetic field strength 14 is adjusted to match the field strength 12 measured at that location 34. Then the rest of the preflight is completed 36 and the UAV is launched within the ROW 38. If the UAV is carried or flown further away from the phase conductors 46, 48, and 50, then sensor 12 will measure a field strength lower than the reference 14. Comparator 16 will cause parachute trigger 19 to deploy parachute 18. This stops the UAV from flying much beyond virtual tunnel 22.

If field strength sensor 12 is adjustable, then it is adjusted while reference field strength 14 is held fixed. If the UAV is specialized for specific line voltages and geometries, then reference field strength 14 may be a fixed value.

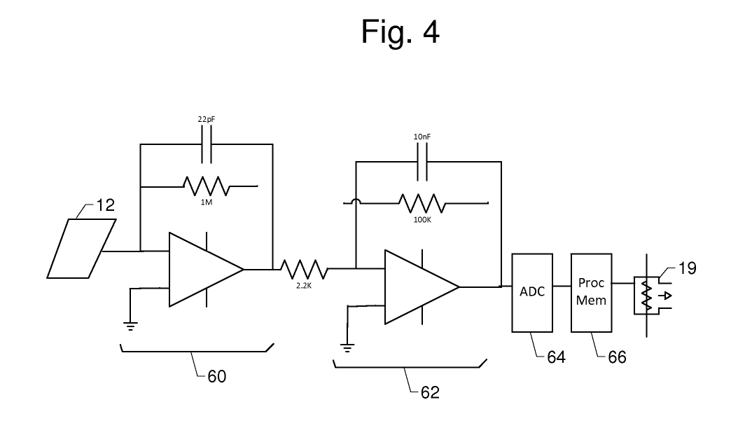

FIG. 4 shows a digital circuit implementation. Electromagnetic field sensor 12 provides an analog signal to a preamplifier 60. After preamplification, the signal then passes through a low pass filter 62 before being digitized by an analog to digital converter 64. The digital signal is filtered with a bandpass filter centered at 60 Hz (50 Hz outside North America) and averaged. The averaged value is compared by processor and memory 66 against the reference electromagnetic field strength 14 previously stored in processor and memory 66. If the averaged signal is less than the reference electromagnetic field strength 14, then trigger 19 is activated to deploy parachute 18.

This section illustrated details of specific embodiments, but persons skilled in the art can readily make modifications and changes that are still within the scope.

We claim:

1. A method for constraining an unmanned aerial vehicle with a parachute during aerial inspection of overhead lines comprising:
storing a reference electromagnetic field strength prior to flight of said unmanned aerial vehicle,
measuring electromagnetic field strength from said overhead lines at said unmanned aerial vehicle during flight,
comparing said measured field strength against said stored reference field strength, triggering said parachute when said comparison detects said measured field strength is less than said stored reference field strength,
whereby said unmanned aerial vehicle is constrained to fly within a virtual tunnel around said overhead lines.

2. The method of claim 1 wherein said storing reference electromagnetic field strength comprises the steps of:
bringing said UAV near edge of right of way of said overhead lines,
measuring electromagnetic field strength at said location near edge of right of way,
saving said measured electromagnetic field strength at said location near edge of right of way as reference electromagnetic field strength.

3. The method of claim 1 wherein said storing reference electromagnetic field strength comprises the steps of:
calculating the expected electric field produced by said overhead lines,
saving its strength at the largest distance of the planned flight path from said overhead lines.

4. A constraint system for unmanned aerial vehicles inspecting overhead lines comprising:
a sensor to measure electromagnetic field strength from said overhead lines during flight of said unmanned aerial vehicle,
means to store a reference electromagnetic field strength prior to flight of said unmanned aerial vehicle,
a parachute mounted on said unmanned aerial vehicle,
a trigger mounted on said unmanned aerial vehicle to open said parachute,
a comparator to activate said trigger when electromagnetic field strength measured by said sensor is less than said stored reference electromagnetic field strength,
whereby said unmanned aerial vehicle is constrained to fly within a virtual tunnel around said overhead lines.
